(19) United States
(12) Patent Application Publication
(10) Pub. No.: US 2023/0121048 A1
(43) Pub. Date: Apr. 20, 2023

(54) BUILDING EVALUATION METHOD, BUILDING EVALUATION APPARATUS, AND NON-TRANSITORY COMPUTER-READABLE STORAGE MEDIUM

(71) Applicant: Panasonic Intellectual Property Management Co., Ltd., Osaka (JP)

(72) Inventor: TETSUYA TAKAYANAGI, Tokyo (JP)

(21) Appl. No.: 18/145,131

(22) Filed: Dec. 22, 2022

Related U.S. Application Data
(63) Continuation of application No. PCT/JP2021/022955, filed on Jun. 16, 2021.

(30) Foreign Application Priority Data
Jul. 10, 2020 (JP) 2020-118958

(51) Int. Cl. G06F 30/28; G06F 30/13; G06Q 30/018

(52) U.S. Cl. CPC G06F 30/28; G06F 30/13; G06Q 30/018

(57) ABSTRACT

A building evaluation method for evaluating a space inside a building on a basis of features used for certain building certification. The building evaluation method includes conducting a thermo-fluid analysis on the space using a feature value of the space that is set for a first feature and whose change causes a change in an evaluation value of the first feature, the thermo-fluid analysis being conducted under each of two or more conditions between which the feature value is different, calculating, on a basis of a result of the thermo-fluid analysis, a correlation coefficient of an evaluation value of each of second features in relation to the feature value, the features being the first feature and the second features, and finding, among the second features, correlation features, whose calculated correlation coefficients satisfy a certain condition and outputting the correlation features.

### BACKGROUND

### 1. Technical Field

The present disclosure relates to a building evaluation method, a building evaluation apparatus, and a non-transitory computer-readable storage medium.

### 2. Description of the Related Art

Techniques relating to evaluation of buildings such as houses have been proposed. In Japanese Unexamined Patent Application Publication No. 2002-38583, for example, a building evaluation method for evaluating a building using information obtained from sensors provided for the building at various positions is disclosed.

### SUMMARY

In the evaluation of a building employing the above building evaluation method or the like, information beneficial to designing of the building based on the evaluation might not be provided. One non-limiting and exemplary embodiment provides a building evaluation method and the like capable of providing more beneficial information.

In one general aspect, the techniques disclosed here feature a building evaluation method for evaluating a space inside a building on a basis of features used for certain building certification. The building evaluation method includes conducting a thermo-fluid analysis on the space using a feature value of the space that is set for a first feature and whose change causes a change in an evaluation value of the first feature, the thermo-fluid analysis being conducted under each of two or more conditions between which the feature value is different, calculating, on a basis of a result of the thermo-fluid analysis, a correlation coefficient of an evaluation value of each of second features in relation to the feature value, the features being the first feature and the second features, and finding, among the second features, correlation features, whose calculated correlation coefficients satisfy a certain condition and outputting the correlation features.

With the building evaluation method according to the aspect of the present disclosure and the like, more beneficial information can be provided.

It should be noted that this general or specific aspect may be implemented as an apparatus, a system, an integrated circuit, a computer program, a computer-readable storage medium, or any selective combination thereof. The computer-readable storage medium includes, for example, a nonvolatile storage medium such as a compact disc read-only memory (CD-ROM).

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a schematic diagram illustrating an example of use of a building evaluation apparatus according to an embodiment;

FIG. 2 is a block diagram illustrating a functional configuration of a system including the building evaluation apparatus according to the embodiment;

FIG. 3 is a flowchart illustrating the operation of the system including the building evaluation apparatus according to the embodiment;

FIG. 4 is a diagram illustrating an example of a method for calculating a correlation coefficient calculated in the embodiment;

FIG. 5 is a first diagram illustrating information output in the embodiment;

FIG. 6 is a second diagram illustrating information output in the embodiment;

FIG. 7 is a third diagram illustrating information output in the embodiment; and

FIG. 8 is a fourth diagram illustrating information output in the embodiment.

### DETAILED DESCRIPTIONS

### Underlying Knowledge Forming Basis of Present Disclosure

During these years, a building certification system called “WELL Building Standard” (registered trademark; hereinafter also referred to as “WELL certification”) is attracting attention. WELL certification is one of building certification systems that evaluate buildings with features based on perspectives including design, construction, and operation, as well as human perspectives such as human health, wellness, and comfort. WELL certification is rapidly spreading around the world including our country.

In WELL certification, a building is evaluated by evaluating spaces inside the building. WELL certification includes over one hundred features. In revised WELL certification launched on May 31, 2018 (hereinafter referred to as “WELL certification v2” or simply as “WELL certification” without being distinguished from the previous WELL certification), the features are classified into ten categories, namely air, water, nourishment, light, movement, thermal comfort, sound, materials, mind, and community. In WELL certification, features are set for each of these categories. In some of these categories including air, light, and thermal comfort, reference values are provided so that achievement of main features can be evaluated with values.

Each of the features of WELL certification is classified, for example, as a precondition or an optimization. A precondition is a feature that needs to be achieved for certification. An optimization is a feature that need not be achieved (i.e., non-precondition). In WELL certification, however, some optimizations need to be selectively achieved. That is, optimizations are achieved to add points in order for a building to obtain certification. In WELL certification, a building that achieves more optimizations can obtain higher-grade certification.

In building certifications with features, including WELL certification, workers perform environmental measurement at measurement points using measuring devices in order to evaluate a building. A method has also been developed in which a sensor is provided for a building at each of measurement points, results of environmental measurement are obtained from the sensors, and the building is evaluated (refer to Japanese Unexamined Patent Application Publication No. 2002-38583).

With such a method based on measurement performed in real space, however, evaluation for certifying a building can be performed only after the building is constructed. If fatal non-achievement of a feature is found, therefore, major reconstruction might need to be performed to achieve the feature. The present disclosure, therefore, focuses upon increases in available computing resources, which are attracting attention during these years, such as cloud systems and distributed computing, and uses a method in which computer-aided engineering (CAE) is used to conduct numerical analyses for certification features in order to evaluate a building.

A building evaluation method and the like capable of providing, before construction of a building (design stage), more beneficial information including relative relationships between features by identifying the relative relationships while conducting numerical analyses will be described.

### Outline of Disclosure

A building evaluation method according to an aspect of the present disclosure is a building evaluation method for evaluating a space inside a building on a basis of features used for certain building certification. The building evaluation method includes conducting a thermo-fluid analysis on the space using a feature value of the space that is set for a first feature and whose change causes a change in an evaluation value of the first feature, the thermo-fluid analysis being conducted under each of two or more conditions between which the feature value is different, calculating, on a basis of a result of the thermo-fluid analysis, a correlation coefficient of an evaluation value of each of second features in relation to the feature value, the features being the first feature and the second features, and finding, among the second features, correlation features, whose calculated correlation coefficients satisfy a certain condition and outputting the correlation features.

With the method for evaluating a building, among features, ones that change in accordance with a change in the evaluation value of the first feature can be found as correlation features. When the feature value is changed in order to improve the evaluation value of the first feature, for example, second features that deteriorate as a result of the change in the evaluation value can be found. The above information is important when such features showing dichotomy are tuned and an optimal level of the feature value is determined. When features are tuned and an optimal level of the feature value is found, therefore, more beneficial information can be provided.

For example, in the certain building certification, each of the features may be classified as a precondition, which needs to be achieved for the building to obtain the certain building certification, or a non-precondition, which need not be achieved for the building to obtain the certain building certification. In the finding, an output priority level of, among the found correlation features, a correlation feature corresponding to one of the preconditions may be set higher than an output priority level of a correlation feature corresponding to one of the non-preconditions and the correlation features may be output in accordance with set output priority levels.

As a result, in the building certification, it becomes less likely that important preconditions are overlooked due to omissions in the output. More beneficial information, therefore, can be provided.

For example, the building evaluation method may further include displaying the output correlation features in modes based on magnitude of the calculated correlation coefficients.

As a result, the output correlation features can be visually checked. More beneficial information, therefore, can be provided.

For example, the certain condition may be that an absolute value of the calculated correlation coefficient be larger than a threshold.

As a result, features whose absolute values of correlation coefficients are larger than the threshold can be found as correlation features. More beneficial information, therefore, can be provided.

For example, the certain condition may be that, in descending order of an absolute value of the calculated correlation coefficient, the second feature be one of a certain number of features with the largest absolute values.

As a result, features included in the certain number of features with the largest absolute values in descending order of an absolute value of a calculated correlation coefficient can be found as correlation features. More beneficial information, therefore, can be provided.

For example, in the finding, information regarding the feature value may be output along with the correlation features.

As a result, information with which the correlation features and the feature value set for the feature can be simultaneously recognized can be displayed. More beneficial information, therefore, can be provided.

For example, in the calculating, dependence of the evaluation value of the first feature upon the feature value may also be determined on a basis of the result of the thermo-fluid analysis. In the finding, a relative relationship between a target value that is a level of the feature value necessary for the evaluation value of the first feature to satisfy a reference value, which is provided for the first feature and is a reference for achieving the first feature, and that is calculated from the reference value on a basis of the determined dependence and a current value, which is a level of the feature value under a current condition, may be output as the information regarding the feature value.

As a result, how the target value for achieving the first feature can be achieved by changing the current feature value can be visually indicated. More beneficial information, therefore, can be provided.

For example, each of the features may include two or more sub-features, each of which is provided with a sub-reference value. A reference value may be satisfied when an evaluation value of the feature satisfies all the sub-reference values of the two or more sub-features. A target value may be calculated on a basis of calculated dependence using a sub-reference value whose difference from a current value is the largest among the two or more sub-reference values.

As a result, when the target value of the feature is satisfied, all the sub-features are invariably achieved, and certification can be certainly obtained.

For example, in the building evaluation method, the certain building certification may be WELL Building Standard (registered trademark).

As a result, information for facilitating obtainment of WELL certification can be provided using the building evaluation method in the present disclosure. More beneficial information, therefore, can be provided.

A non-transitory computer-readable storage medium according to another aspect of the present disclosure is a non-transitory computer-readable storage medium storing a program for causing a computer to perform the building evaluation method.

As a result, the same advantageous effect as that produced by the building evaluation method can be produced using the computer.

A building evaluation apparatus according to another aspect of the present disclosure is a building evaluation apparatus that evaluates a space inside a building on a basis of features used for certain building certification. The building evaluation apparatus includes an analyzer that conducts a thermo-fluid analysis on the space using a feature value of the space that is set for a first feature and whose change causes a change in an evaluation value of the first feature, the thermo-fluid analysis being conducted under each of two or more conditions between which the feature value is different, a calculator that calculates, on a basis of a result of the thermo-fluid analysis, a correlation coefficient of an evaluation value of each of second features in relation to the feature value, the features being the first feature and the second features, and an outputter that finds, among the second features, correlation features, whose calculated correlation coefficients satisfy a certain condition and that outputs the correlation features.

As a result, the same advantageous effect as that produced by the building evaluation method can be produced.

An embodiment will be specifically described hereinafter with reference to the drawings.

The embodiment described hereinafter is a general or specific example. Values, shapes, materials, components, arrangement positions and connection modes of the components, steps, order of the steps, and the like described in the following embodiment are examples, and not intended to limit the claims. The drawings are not necessarily strict illustrations. In the drawings, substantially the same components are given the same reference numerals, and redundant description thereof might be omitted or simplified.

In the following description, terms indicating relationships between elements, such as parallel and perpendicular, terms indicating shapes of elements, such as rectangular, and numerical ranges need not be strictly interpreted, and may include substantially the same ranges with a difference of, say, several percent.

Among the components described in the following embodiment, ones not described in the independent claims will be described as optional components.

### EMBODIMENT

### Configuration

First, an example of use of a building evaluation apparatus according to the present embodiment will be described. FIG. 1 is a schematic diagram illustrating an example of use of the building evaluation apparatus according to the embodiment. FIG. 1 illustrates a building evaluation apparatus 100 and a terminal apparatus 200 connected to the building evaluation apparatus 100.

In the present embodiment, the building evaluation apparatus 100 is achieved, for example, in a cloud server. A user 99 uses the building evaluation apparatus 100 by, for example, accessing the building evaluation apparatus 100 through the terminal apparatus 200. The terminal apparatus 200 is a mobile device such as a smartphone, a tablet terminal, or a personal computer (PC) and carried by the user 99. The user 99 is, for example, a consultant who provides advice on designs and the like of buildings for obtaining WELL certification. The user 99, upon consultation with an owner of a building or another person, modifies designs of the building that the owner desires to build into ones with which WELL certification can be obtained, or provides advice such as guidelines for modification. The user 99 obtains basic data regarding the building from the owner or another person and modifies, on the basis of the basic data, the designs of the building into ones with which WELL certification can be obtained.

For example, the user 99 obtains, from an owner of a building or another person, three-dimensional computer-aided design (CAD) data indicating information regarding a structure of the building and the like and transmits the CAD data to the building evaluation apparatus 100 through the terminal apparatus 200. The user 99 receives the information output from the building evaluation apparatus 100 with the terminal apparatus 200, displays the information, and modifies the CAD data or provides guidelines for modification of the building for the owner or another person. The user 99 and the owner or another person thus communicate with each other before construction of the building to create designs of the building with which WELL certification can be obtained. Since evaluation is performed for WELL certification or the like on the basis of performance of equipment provided for a building, including air conditioning devices and humidity and heat devices, the basic data includes information regarding such equipment. In the present embodiment, the user 99 obtains building information modeling (BIM) data as information that can include both three-dimensional CAD data and numerical data regarding arrangement positions and performance of equipment and the like.

Such an embodiment is an example. For example, the building evaluation apparatus 100 may be achieved as a web service, or individual users 99 may access the building evaluation apparatus 100 using terminal apparatuses 200 owned thereby and create designs of buildings with which WELL certification can be obtained. The building evaluation apparatus 100 may be operated without using the terminal apparatus 200. For example, the building evaluation apparatus 100 can be achieved as an independent apparatus by incorporating part of functions of the terminal apparatus 200 into an apparatus for achieving the building evaluation apparatus 100, such as a computer. The building evaluation apparatus 100 may thus be achieved by apparatuses each having a different part of the functions thereof or an independent apparatus having all the functions thereof.

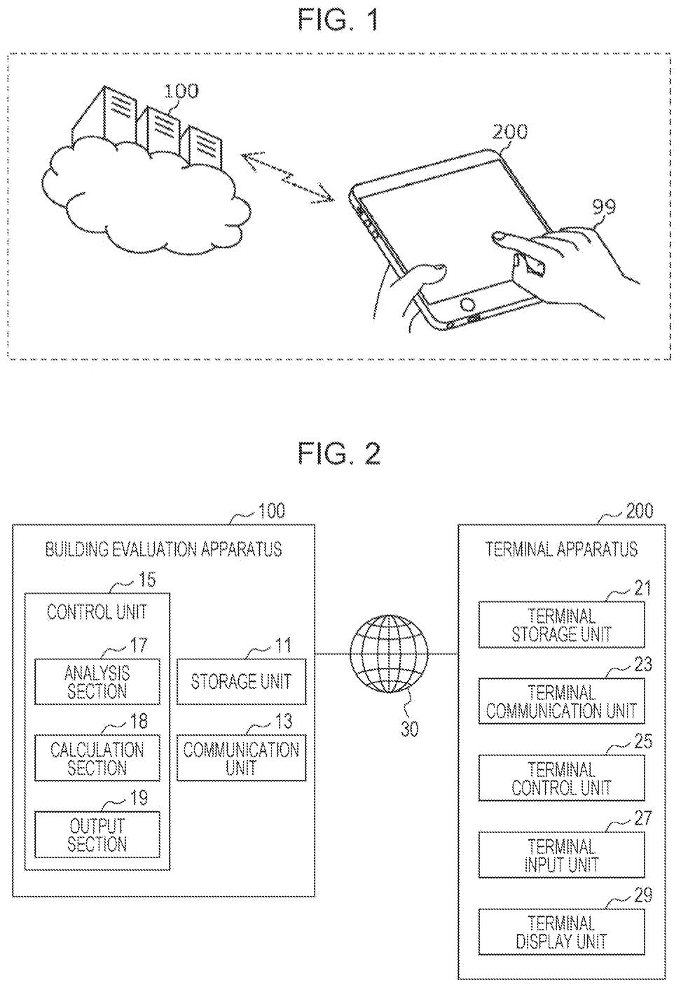

Next, functional configurations of the building evaluation apparatus 100 and the like will be described with reference to FIG. 2. FIG. 2 is a block diagram illustrating a functional configuration of a system including the building evaluation apparatus according to the embodiment. FIG. 2 illustrates, as with FIG. 1, the building evaluation apparatus 100 and the terminal apparatus 200 connected to the building evaluation apparatus 100.

In the present embodiment, the building evaluation apparatus 100 and the terminal apparatus 200 are communicably connected to each other over a network 30. The network 30 may be any communication network capable of achieving a communicable link, and a communication method and a communication mode, such as wired or wireless, thereof are not particularly limited.

The building evaluation apparatus 100 according to the present embodiment evaluates spaces inside a building with features used for certain building certification. In the following description, the certain building certification is the above-described WELL certification. Content of the present disclosure, however, may be applied to any building certification employing features, such as LEED (registered trademark) certification or CASBEE (registered trademark) certification. The building evaluation apparatus 100 includes a storage unit 11, a communication unit 13, and a control unit 15. The control unit 15 includes an analysis section 17, a calculation section 18, and an output section 19.

The storage unit 11 is a storage device storing various pieces of information used to operate the building evaluation apparatus 100. The storage unit 11 is achieved by a semiconductor memory, a magnetic storage device, an optical storage device, or the like.

The communication unit 13 is a communication module for communicating various pieces of information between the building evaluation apparatus 100 and an external apparatus such as the terminal apparatus 200. For example, the communication unit 13 outputs and transmits images as information to be displayed on the terminal apparatus 200. The terminal apparatus 200 receives the images over the network 30 and displays the images on a terminal display unit 29 thereof, which will be described later.

The control unit 15 is a functional unit that performs information processing in the building evaluation apparatus 100. The control unit 15 is achieved by executing certain programs for information processing using a processor, a memory, and the like.

The analysis section 17 is achieved by executing, using the control unit 15, a program relating to information processing performed thereby. The analysis section 17 conducts a thermo-fluid analysis on spaces inside a building to be evaluated. BIM data regarding a building, therefore, is provided for the analysis section 17. The analysis section 17 conducts a thermo-fluid analysis on spaces inside a building on the basis of the BIM data under a set analysis condition. As a result of the thermo-fluid analysis conducted by the analysis section 17, an evaluation value of each of the features of WELL certification under the set analysis condition is obtained.

The analysis condition for the thermo-fluid analysis includes various parameters such as boundary conditions set for entrances, ventilation openings, windows, and the like provided at certain positions in the spaces, open or closed states of doors and sashes that partition the entrances and the windows, ventilation flow rates from the ventilation openings, operational settings of equipment such as air conditioning devices, and the amount of CO2 generated based on the amount of respiration by the maximum number of people active in the spaces, radiant heat caused by sunlight and artificial light, and a value or the like is set for each of these parameters. The value or the like may be one incorporated into BIM data or one obtained as a result of modification performed by the user 99 or another person. When the user 99 does not particularly modify any of the parameters, for example, closed states of doors and sashes, a ventilation flow rate of 0.3 air change per hour (ACH), and operational settings of air conditioning devices to be installed are set as the analysis condition.

With respect to features based on substance concentration or the like among the features of WELL certification, usually assumed values are used as initial values of the substance concentration. When the building evaluation apparatus 100 is used in order to reconstruct a constructed building and create designs with which WELL certification can be obtained, however, values measured in spaces inside the actual building may be used, instead.

In the thermo-fluid analysis, an algorithm based on a finite element method or a finite volume method, such as Navier-Stokes equations, may be used, or an algorithm with a high affinity for parallel computing, such as a lattice Boltzmann method, may be used. The use of the lattice Boltzmann method as an algorithm for the thermo-fluid analysis has an advantage of greatly reducing computation time using parallel computing when a computer used is a multi-core or many-core processor. Since the thermo-fluid analysis is a process that involves an enormous amount of computation, an analysis range (i.e., a target space) of one room, one floor, one building, or the like may be set in accordance with computing resources available to the building evaluation apparatus 100 in consideration of speed and accuracy of computation or the like.

The calculation section 18 is achieved by executing, using the control unit 15, a program relating to information processing performed thereby. The calculation section 18 performs calculation relating to correlations between features.

More specifically, for each of the features, a value based on the parameters of the analysis condition that can vary an evaluation value of the feature and that can be adjusted by changing designs or equipment inside a building or through reconstruction is set in advance as a feature value of spaces. That is, an evaluation value of a feature varies by changing a feature value of spaces set for the feature. A feature value may be, for example, a value obtained by calculating parameters or a parameter itself when appropriate for the feature.

A feature value does not affect only one feature and can affect two or more features in a complex manner. When a feature value is changed in order to improve an evaluation value of a certain feature, therefore, the change might undesirably decrease an evaluation value of another feature. By identifying a correlation coefficient between a feature and a changed feature value, therefore, strength of correlation between a feature and another feature can be quantified.

In the present embodiment, the building evaluation apparatus 100 can provide information for identifying a feature value to be changed by identifying a feature highly correlated with another feature as described above.

The output section 19 is achieved by executing, using the control unit 15, a program relating to information processing performed thereby. The output section 19 identifies, as a correlation feature, a feature whose calculated correlation coefficient satisfies a certain condition and outputs the correlation feature to an external apparatus through the communication unit 13.

First, the output section 19 obtains, from the user 99, information regarding a feature to be focused upon. The output section 19 identifies another feature that satisfies a certain condition for the feature to be focused upon by the user 99. The certain condition is, for example, that an absolute value of a calculated correlation coefficient be larger than a threshold. As a result, a highly correlated feature whose correlation coefficient is higher than or equal to the threshold can be identified. The certain condition may be, for example, that, in descending order of the absolute value of a calculated correlation coefficient, a feature be one of a certain number of features with the largest absolute values, instead. As a result, features can be identified in descending order of the correlation coefficient. A certain number of features can be identified and output.

Since preconditions need to be achieved in WELL certification, the preconditions may be preferentially output. For example, the output section 19 sets output priority levels of correlation features corresponding to the preconditions among identified features higher than those of correlation features corresponding to non-preconditions and outputs the correlation features in accordance with the set output priority levels. As a result, highly correlated features corresponding to preconditions can be output for a feature focused upon by the user 99. Because the user 99 can select a feature value to be changed while checking preconditions associated with the feature to be focused upon, the user 99 can create more appropriately designs with which WELL certification can be obtained. That is, the building evaluation apparatus 100 can provide more beneficial information.

The terminal apparatus 200 includes a terminal storage unit 21, a terminal communication unit 23, a terminal control unit 25, a terminal input unit 27, and a terminal display unit 29.

The terminal storage unit 21 is a storage device storing various pieces of information to be used to operate the terminal apparatus 200. The terminal storage unit 21 is achieved by a semiconductor memory, a magnetic storage device, an optical storage device, or the like.

The terminal communication unit 23 is a communication module that communicates various pieces of information between the terminal apparatus 200 and an external apparatus such as the building evaluation apparatus 100. For example, the terminal communication unit 23 transmits BIM data regarding a building input from the terminal input unit 27, which will be described later, to the building evaluation apparatus 100 over the network 30.

The terminal control unit 25 is a functional unit that performs information processing in the terminal apparatus 200. The terminal control unit 25 is achieved when a certain program relating to the information processing is executed using a processor, a memory, and the like.

The terminal input unit 27 is a communication port for allowing the user 99 to input information to the terminal apparatus 200. The terminal input unit 27 includes a socket and obtains information stored in an information device including a plug when the information device is connected to the socket. When an information device that is owned by an owner of a building or another person and that stores BIM data is connected, for example, the terminal apparatus 200 owned by the user 99 can obtain the BIM data owned by the owner or another person. The BIM data obtained by the terminal input unit 27 is transmitted to the building evaluation apparatus 100 through the terminal communication unit 23.

The terminal display unit 29 is a display device including a display panel achieved by light-emitting diodes (LEDs), organic electroluminescence (EL), liquid crystal, or the like. The terminal display unit 29 can display an operation state of the terminal apparatus 200 and the like, images obtained from the building evaluation apparatus 100, and the like.

### Operation

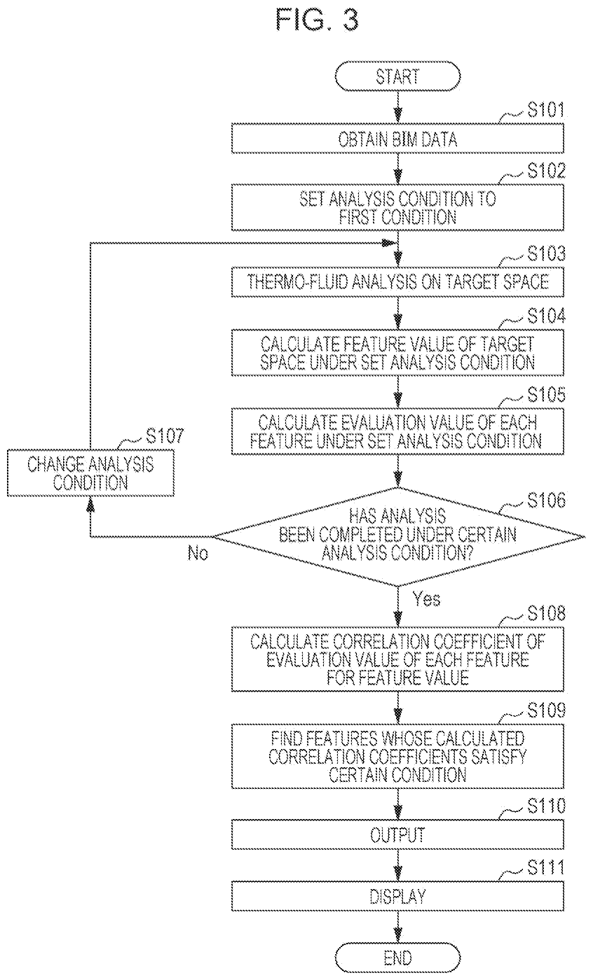

Next, the operation of the building evaluation apparatus 100 described above will be described with reference to FIGS. 3 to 8. FIG. 3 is a flowchart illustrating the operation of the system including the building evaluation apparatus according to the embodiment. Here, a state where a feature to be focused upon by the user 99 has been set will be described. That is, an operation performed by the building evaluation apparatus 100 where correlations between a set feature and other features are analyzed and collected and a feature with which a correlation satisfies a certain condition is output will be described.

First, the building evaluation apparatus 100 obtains BIM data through the terminal apparatus 200 (step S101). The analysis section 17 sets the analysis condition to a first condition (step S102) and conducts a thermo-fluid analysis on a target space on the basis of the obtained BIM data (analysis step S103).

The analysis section 17 calculates a feature value under the set analysis condition (step S104). The feature value is calculated using a value of each of the parameters. The analysis section 17 comprehensively calculates evaluation values of other features under the set analysis condition (step S105).

Here, the analysis section 17 determines whether the analysis has been completed under a certain analysis condition (step S106). The certain analysis condition is determined on the basis of whether a preset number of sets of a feature value and an evaluation value of another feature have been obtained. If at least part of the analysis has not been conducted under the certain analysis condition (NO in step S106), the analysis condition is changed (step S107), and the analysis starts again from step S103.

In the change of the analysis condition in step S107, the original analysis condition is changed to another analysis condition whose feature value is different. That is, by repeating steps S102 to S107, a dataset of evaluation values of other features corresponding to each of different feature values is created. A correlation coefficient between a feature value set for a feature focused upon by the user 99 and each of evaluation values of other features is calculated in accordance with the dataset. The preset number of sets set for the certain analysis condition, therefore, is set to the number of datasets with which accuracy of correlation coefficients is secured.

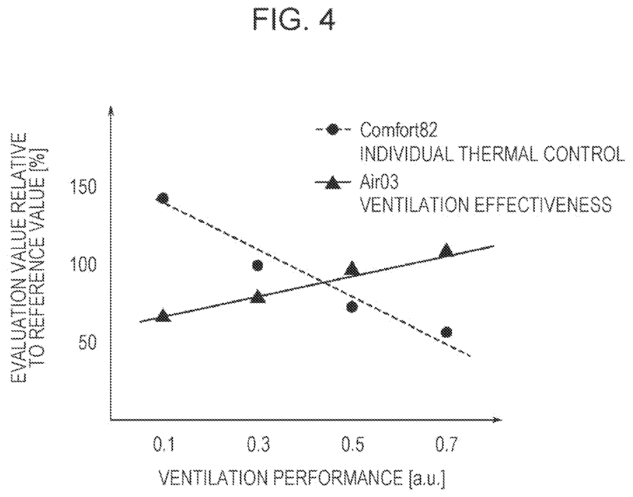

If the analysis has been completed under the certain analysis condition (YES in step S106), the calculation section 18 calculates a correlation coefficient of an evaluation value of each of the features (calculation step S108). FIG. 4 is a diagram illustrating an example of a method for calculating a correlation coefficient calculated in the embodiment. FIG. 4 is a graph in which an evaluation value of comfort category No. 82 “individual thermal control” (Comfort82), whose correlation coefficient in relation to ventilation performance, which is a feature value of air category No. 03 “ventilation efficiency” (Air03) and is a feature focused upon by the user 99, is relatively high, is plotted with the ventilation performance represented by a horizontal axis.

As illustrated in FIG. 4, as the ventilation performance, which is the feature value of Air03, increases, an evaluation value of Air03 increases. That is, it can be seen that Air03 is evaluated more highly by improving the ventilation performance. On the other hand, as the ventilation performance, which is the feature value of Air03, increases, the evaluation value of Comfort82 decreases. That is, it can be seen that Comfort82 is evaluated more poorly by improving the ventilation performance. In other words, the features Air03 and Comfort82 show dichotomy in relation to the feature value of the ventilation performance.

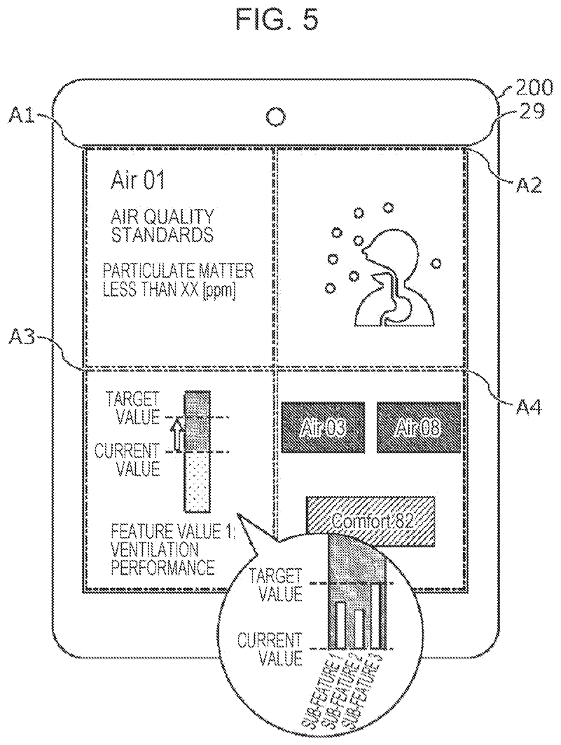

FIG. 3 will be referred to again. Next, the output section 19 finds, among the other features, features whose correlation coefficients calculated by the calculation section 18 satisfy a certain condition (step S109). The output section 19 outputs, through the communication unit 13, information indicating the found features (output step S110). The terminal communication unit 23 of the terminal apparatus 200 receives the output information, and the terminal display unit 29 displays the information (display step S110). FIG. 5 illustrates an example of the displayed information. FIG. 5 is a first diagram illustrating information output in the embodiment. FIG. 5 illustrates an example where three features with highest correlation coefficients have been found. As illustrated in FIG. 5, the terminal display unit 29 of the terminal apparatus 200 displays different pieces of information in four areas, namely areas A1 to A4, of a screen. Dash-dot lines defining the areas are shown for convenience and not displayed in practice.

In the area A1, for example, a name of a feature focused upon and a condition of achievement are displayed. In the example illustrated in FIG. 5, the feature focused upon is air category No. 01 “air quality standards” (Air01), and the condition of achievement is “particulate matter less than XX [ppm]”.

In the area A2, an illustration relating to Air01, which is the feature focused upon, is displayed.

In the area A3, information about a feature value is displayed. Although not illustrated, the calculation section 18 has calculated in advance, on the basis of a result of the thermo-fluid analysis, dependence of the evaluation value of Air01 upon the feature value (i.e., an approximate curve of the evaluation value in relation to the feature value). A graph indicating a relative relationship between a target value, which is a level of the feature value necessary for the evaluation value of Air01, which is the feature focused upon, to satisfy a reference value for achieving Air01, which is provided for Air01 and calculated using the dependence, and a current value, which is a level of the feature value under a current condition, is shown.

Air01 includes three sub-features, each of which is provided with a sub-reference value. The reference value is satisfied when the evaluation value of Air01 satisfies the sub-reference values of all the three sub-features. The target value, therefore, is set on the basis of, among the three sub-reference values, a sub-reference value with a largest difference from a current value. As a result, when the target value of the feature is satisfied, all the sub-features are invariably achieved, and certification can be certainly obtained.

In the area A4, found features are displayed. Here, Air03 and Air08, which have a positive correlation with the feature value set for Air01, and Comfort82, which has a negative correlation with the feature value set for Air01, are displayed differently. For example, at least color or brightness is displayed differently.

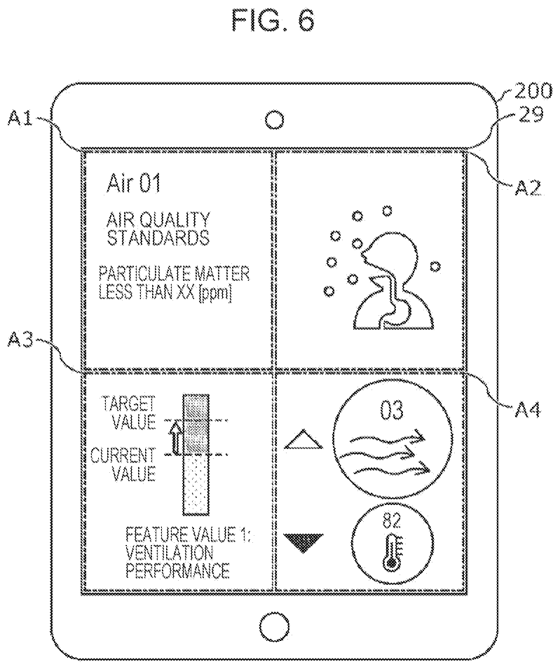

Another example of the displayed information will be described with reference to FIG. 6. FIG. 6 is a second diagram illustrating information output in the embodiment. In FIG. 6, description of the same elements as in FIG. 5 is omitted by referring to FIG. 5.

In the example illustrated in FIG. 6, information displayed in the area A4 is different from that displayed in the area A4 in the example illustrated in FIG. 5. More specifically, Air03 and Comfort82 are both displayed as icons. More specifically, Air03 is displayed as an icon including an illustration that indicates that Air03 is a feature relating to air. Comfort82 is displayed as an icon including an illustration indicating that Comfort82 is a feature relating to temperature. The icon of Air03 is displayed larger than that of Comfort82. The sizes of the icons are determined in accordance with correlation coefficients. That is, the correlation coefficient of Air03 is higher than that of Comfort82. Whether a correlation is positive or negative is indicated by a triangle or an inverted triangle shown next to an icon. For example, a triangle is given to Air03 to indicate a positive correlation, and an inverted triangle is given to Comfort82 to indicate a negative correlation.

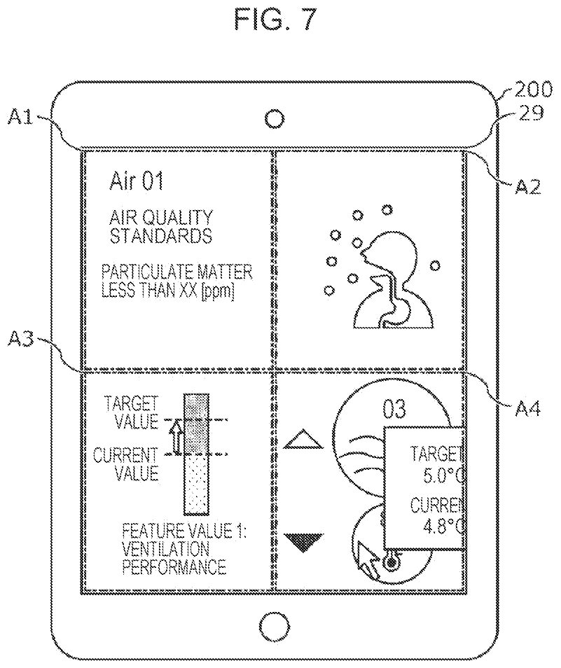

Another example of the displayed information will be described with reference to FIG. 7. FIG. 7 is a third diagram illustrating information output in the embodiment. In FIG. 7, description of the same elements as in FIG. 6 is omitted by referring to FIG. 6.

In the example illustrated in FIG. 7, a cursor has been moved over the icon of Comfort82 in the area A4. When the user 99 moves the cursor over an icon, detailed information may also be displayed in a pop-up window as illustrated in FIG. 7. Here, a current value and a target value for achieving Comfort82 are displayed.

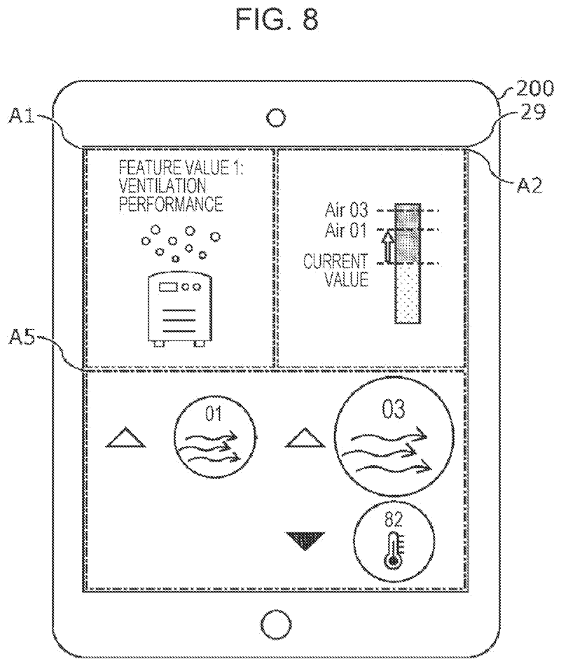

Another example of the displayed information will be described with reference to FIG. 8. FIG. 8 is a fourth diagram illustrating information output in the embodiment. In FIG. 8, description of the same elements as in FIG. 5 is omitted by referring to FIG. 5.

In the example illustrated in FIG. 8, the terminal display unit 29 of the terminal apparatus 200 displays different pieces of information in three areas, namely the area A1, the area A2, and an area A5, which has a size of the areas A3 and A4 combined together, of the screen. Dash-dot lines defining the areas are shown for convenience and not displayed in practice.

Unlike in the above three examples, information relating to a feature focused upon is not mainly displayed but information relating to a feature value of the feature focused upon is displayed in each of the areas in this example. In the area A1, for example, characters and an illustration indicating that information relates to ventilation performance, which is a feature value, are displayed.

In the area A2, amounts of increase or decrease in the currently displayed feature value necessary to achieve certain features are visually indicated.

Since a target value of a feature (here, Air01) corresponding to the currently displayed feature value and target values (i.e., sub-target values) of other features (here, Air03 and Comfort82) at a time when the feature value is changed are visually indicated on a single axis of change of the feature value, a relationship between these values can be intuitively evaluated. The target values of the other features are set, on the basis of dependence (i.e., sub-dependence) of evaluation values of the other features upon the feature value set for the feature, as levels of the feature value at a time when the evaluation values satisfy corresponding reference values (i.e., sub-reference values) set for the other features.

In the area A5, the icons of the correlated features illustrated in FIGS. 6 and 7 are displayed. Whereas the number of icons indicating found features is two in FIGS. 6 and 7, three icons are displayed in this example, that is, the number of found features is three. The number of features to be found may dynamically change in accordance with the display area of an area in which information is to be displayed.

### OTHER EMBODIMENTS

Although an embodiment and the like have been described above, the present disclosure is not limited to the above embodiment and the like.

Although the components of the building evaluation apparatus and the like have been described in the above embodiment and the like, the functions of the components of the building evaluation apparatus and the like may be distributed between the components of the building evaluation apparatus and the like in any manner.

The present disclosure also includes modes obtained by modifying the above embodiment and the like in various ways conceivable by those skilled in the art and modes achieved by combining together components and functions in the above embodiment and the like in any manner without deviating from the scope of the present disclosure.

In the above embodiment, each component such as the control unit may be achieved by executing a software program suitable for the component, instead. Each component may be achieved when a program execution unit such as a central processing unit (CPU) or a processor reads a software program stored in a storage medium such as a hard disk or a semiconductor memory and executing the software program, instead.

Each component such as the control unit may be achieved by hardware, instead. Each component may be a circuit (or an integrated circuit). Such circuits may together form a single circuit or may be separate circuits. Such circuits may be general-purpose circuits or dedicated circuits.

It should be noted that general or specific aspects of the present disclosure may be implemented as a system, an apparatus, a method, an integrated circuit, a computer program, a storage medium such as a CD-ROM, or any selective combination thereof.

The present disclosure may be implemented as a building evaluation method performed by a computer such as the building evaluation apparatus according to the above embodiment or a program for causing a computer to perform the building evaluation method, instead. The present disclosure may be implemented as a non-transitory computer-readable storage medium storing the program, instead.

The present disclosure is effective in evaluation of a building performed in order to facilitate obtainment of certain certification or the like.

What is claimed is:

1. A building evaluation method for evaluating a space inside a building on a basis of features used for certain building certification, the building evaluation method comprising:
conducting a thermo-fluid analysis on the space using a feature value of the space that is set for a first feature and whose change causes a change in an evaluation value of the first feature, the thermo-fluid analysis being conducted under each of two or more conditions between which the feature value is different;
calculating, on a basis of a result of the thermo-fluid analysis, a correlation coefficient of an evaluation value of each of second features in relation to the feature value, the features being the first feature and the second features; and
finding, among the second features, correlation features, whose calculated correlation coefficients satisfy a certain condition and outputting the correlation features.

2. The building evaluation method according to claim 1,
wherein, in the certain building certification, each of the features is classified as a precondition, which needs to be achieved for the building to obtain the certain building certification, or a non-precondition, which need not be achieved for the building to obtain the certain building certification, and
wherein, in the finding, an output priority level of, among the found correlation features, a correlation feature corresponding to one of the preconditions is set higher than an output priority level of a correlation feature corresponding to one of the non-preconditions and the correlation features are output in accordance with set output priority levels.

3. The building evaluation method according to claim 1, further comprising:
displaying the output correlation features in modes based on magnitude of the calculated correlation coefficients.

4. The building evaluation method according to claim 1,
wherein the certain condition is that an absolute value of the calculated correlation coefficient be larger than a threshold.

5. The building evaluation method according to claim 1,
wherein the certain condition is that, in descending order of an absolute value of the calculated correlation coefficient, the second feature be one of a certain number of features with the largest absolute values.

6. The building evaluation method according to claim 1,
wherein, in the finding, information regarding the feature value is output along with the correlation features.

7. The building evaluation method according to claim 1,
wherein, in the finding, a selected feature value and a feature and a correlation feature corresponding to the selected feature value are output.

8. The building evaluation method according to claim 6,
wherein, in the calculating, dependence of the evaluation value of the first feature upon the feature value is also determined on a basis of the result of the thermo-fluid analysis, and
wherein, in the finding, a relative relationship between a target value that is a level of the feature value necessary for the evaluation value of the first feature to satisfy a reference value, which is provided for the first feature and is a reference for achieving the first feature, and that is calculated from the reference value on a basis of the determined dependence and a current value, which is a level of the feature value under a current condition, is output as the information regarding the feature value.

9. The building evaluation method according to claim 8,
wherein each of the features includes two or more sub-features, each of which is provided with a sub-reference value,
wherein a reference value is satisfied when an evaluation value of the feature satisfies all the sub-reference values of the two or more sub-features, and
wherein a target value is calculated on a basis of calculated dependence using a sub-reference value whose difference from a current value is the largest among the two or more sub-reference values.

10. The building evaluation method according to claim 8,
wherein, in the calculating, sub-dependence of the evaluation value of each of the second features upon the feature value is also determined on a basis of the result of the thermo-fluid analysis, and
wherein, in the finding, a relative relationship between a sub-target value that is a level of the feature value necessary for the evaluation value of the second feature to satisfy a sub-reference value, which is provided for the second feature and is a reference for achieving the second feature, and that is calculated from the sub-reference value on a basis of the determined sub-dependence, a target value, and a current value is output as the information regarding the feature value.

11. The building evaluation method according to claim 1,
wherein the certain building certification is WELL Building Standard (registered trademark).

12. A non-transitory computer-readable storage medium storing a program for causing a computer to perform the building evaluation method according to claim 1.

13. A building evaluation apparatus that evaluates a space inside a building on a basis of features used for certain building certification, the building evaluation apparatus comprising:
an analyzer that conducts a thermo-fluid analysis on the space using a feature value of the space that is set for a first feature and whose change causes a change in an evaluation value of the first feature, the thermo-fluid analysis being conducted under each of two or more conditions between which the feature value is different;
a calculator that calculates, on a basis of a result of the thermo-fluid analysis, a correlation coefficient of an evaluation value of each of second features in relation to the feature value, the features being the first feature and the second features; and
an outputter that finds, among the second features, correlation features, whose calculated correlation coefficients satisfy a certain condition and that outputs the correlation features.
